(19) United States
(12) Patent Application Publication
(10) Pub. No.: US 2013/0087763 A1
(43) Pub. Date: Apr. 11, 2013

(54) LIGHT EMITTING DIODE AND METHOD OF MANUFACTURING THE SAME

(71) Applicants: Sung Bock Kim, Daejeon (KR); Sung-Bum Bae, Daejeon (KR)

(72) Inventors: Sung Bock Kim, Daejeon (KR); Sung-Bum Bae, Daejeon (KR)

(73) Assignee: ELECTRONICS AND TELECOMMUNICATIONS RESEARCH INSTITUTE, Daejeon (KR)

(21) Appl. No.: 13/609,352

(22) Filed: Sep. 11, 2012

(30) Foreign Application Priority Data
Oct. 6, 2011 (KR) 10-2011-0101988
Mar. 7, 2012 (KR) 10-2012-0023634

(51) Int. Cl. H01L 33/06; H01L 33/16

(52) U.S. Cl. 257/13; 438/47; 257/E33.008; 257/E33.003

(57) ABSTRACT

The inventive concept provides light emitting diodes and methods of manufacturing the same. The light emitting diode may include a first electrode layer, a light emitting layer on the first electrode layer, a second electrode layer on the light emitting layer, and a buffer layer formed on the second electrode layer, the buffer layer having concave-convex patterns increasing extraction efficiency of light generated from the light emitting layer.

### CROSS-REFERENCE TO RELATED APPLICATIONS

This U.S. non-provisional patent application claims priority under 35 U.S.C. §119 to Korean Patent Application Nos. 10-2011-0101988 and 10-2012-0023634, filed on Oct. 6, 2011 and Mar. 7, 2012, the entirety of which is incorporated by reference herein.

### BACKGROUND

The inventive concept relates to light emitting diodes and methods of manufacturing the same and, more particularly, to light emitting diodes generating a green light and methods of manufacturing the same.

White light emitting diodes (LEDs) based on gallium nitride (GaN) have more excellent efficiency than a fluorescent lamp, so that the white LEDs are attractive in a next generation general lighting industry. The white LEDs for the lighting may be currently formed by various methods. Mostly, the white LEDs for the lighting may be generally formed by applying yellow phosphor to blue LEDs. Thus, high efficiency blue LEDs have been remarkably developed. The LEDs are devices emitting light. If the LEDs realize all RGB colors corresponding to the three primary colors of light, the LEDs may be widely used in emotional lighting realizing various colors, full color displays, medical/bio field, and agricultural field as well as general lighting. Currently, the blue LED based on GaN may have an external quantum efficiency of 30% or more, a red LED based on GaAs may have an external quantum efficiency of 50% or more. However, a green LED may have a low external quantum efficiency of about 10%.

FIG. 1 is a graph of external quantum efficiency of LEDs according to a wavelength.

Referring to FIG. 1, the dot lines, 10 and 11, present the external quantum efficiency of GaN based light emitting diode grown on a polar (C-plane) substrate and GaAs based light emitting diode, respectively. The green gap 12 has a low efficiency in a wavelength band from a green color to a yellow color of 550 nm to 600 nm. A lattice of the substrate may not be matched with a lattice of the InGaN light emitting layer 10, such that the green gap 12 may occur. The InGaN light emitting layer of a green wavelength may have an indium ratio of about 30% or more, so that a great strain may occur by misfit dislocation. When the InGaN light emitting layer 10 is formed on a GaN substrate or a SiC substrate, the misfit dislocation may be reduced. However, the GaN substrate or the SiC substrate of a large area may be very expensive, so that price of the light emitting diode may be raised. Meanwhile, an InGaN light emitting layer 20 grown on a semi-polar substrate is able to overcome the green gap 12 in a wavelength band from a green color to a yellow color of 520 nm to 600 nm. Thus, the InGaN light emitting layer 20 on the semi-polar substrate has higher efficiency than the InGaN light emitting layer 10 on the polar substrate. However, the semi-polar InGaN light emitting layer 20 may require a semi-polar GaN template of low cost and a large area. The fabricating difficulty of semi-polar GaN template is obstacle to make high efficient green LED.

### SUMMARY

Embodiments of the inventive concept may provide light emitting diodes capable of improving light emitting efficiency and methods of manufacturing the same.

Embodiments of the inventive concept may also provide light emitting diodes capable of improving productivity and methods of manufacturing the same.

In one aspect, a light emitting diode may include: a first electrode layer; a light emitting layer on the first electrode layer; a second electrode layer on the light emitting layer; and a buffer layer formed on the second electrode layer, the buffer layer having concave-convex patterns increasing extraction efficiency of light generated from the light emitting layer.

In some embodiments, convex parts of the concave-convex patterns may be spaced apart from each other by a distance equal to or less than a half width of each of the convex parts.

In other embodiments, each of the convex parts of the concave-convex patterns may have at least one gallium nitride (0001) incline face.

In still other embodiments, the buffer layer may have a semi-polar gallium nitride ( 1̅101) plane.

In yet other embodiments, the light emitting layer may include indium-gallium nitride well layers and gallium nitride barrier layers.

In yet still other embodiments, the buffer layer may have a refractive index of about 1.22 or more.

In another aspect, a method of manufacturing a light emitting diode may include: partially etching a silicon (100) substrate to form trenches exposing silicon (111) incline facets; forming a buffer layer having gallium nitride (0001) incline faces grown from the silicon (111) incline facets and a semi-polar gallium nitride ( 1̅101) plane grown higher than a top surface of the silicon (100) substrate; forming a first electrode layer on the semi-polar gallium nitride ( 1̅101) plane; forming a light emitting layer on the first electrode layer; forming a second electrode layer on the light emitting layer; and removing the silicon (100) substrate.

In some embodiments, forming the buffer layer may include: forming mask patterns exposing the silicon (111) incline facets of the trenches; forming semi-polar gallium nitride patterns having gallium nitride (0001) incline faces grown from the silicon (111) inclined facets and the semi-polar gallium nitride ( 1̅101) planes; and laterally growing the semi-polar gallium nitride patterns to connect the semi- polar gallium nitride ( 1̅101) planes to each other.

In other embodiments, the semi-polar gallium nitride patterns may be laterally grown by a metal organic chemical vapor deposition method of a epitaxial lateral overgrowth condition.

In still other embodiments, wherein the silicon (100) substrate may be removed by a chemical lift-off method using a potassium hydroxide (KOH) solution.

In yet other embodiments, forming the trenches may include: forming mask patterns on the silicon (100) substrate; removing portions of the silicon (100) substrate by an etching process using the mask patterns as etch masks, thereby forming the trenches exposing the silicon (111) incline facets; and removing the mask patterns.

In yet still other embodiments, the etching process may be a wet etching process using a potassium hydroxide (KOH) solution.

In yet still other embodiments, the mask patterns may include silicon nitride.

In yet still other embodiments, the method may further include: bonding the first electrode layer and the second electrode layer to a receptor substrate through stud bumps and an ohmic metal layer in a flip-chip bonding method.

### BRIEF DESCRIPTION OF THE DRAWINGS

The inventive concept will become more apparent in view of the attached drawings and accompanying detailed description.

FIG. 1 is a graph illustrating external quantum efficiency according to a wavelength;

FIG. 2 is a cross-sectional view illustrating a light emitting diode according to embodiments of the inventive concept; and

FIGS. 3 to 12 cross-sectional views illustrating a method of manufacturing a light emitting diode according to embodiments of the inventive concept.

### DETAILED DESCRIPTION OF THE EMBODIMENTS

The inventive concept will now be described more fully hereinafter with reference to the accompanying drawings, in which exemplary embodiments of the inventive concept are shown. The advantages and features of the inventive concept and methods of achieving them will be apparent from the following exemplary embodiments that will be described in more detail with reference to the accompanying drawings. It should be noted, however, that the inventive concept is not limited to the following exemplary embodiments, and may be implemented in various forms. Accordingly, the exemplary embodiments are provided only to disclose the inventive concept and let those skilled in the art know the category of the inventive concept. In the drawings, embodiments of the inventive concept are not limited to the specific examples provided herein and are exaggerated for clarity.

The terminology used herein is for the purpose of describing particular embodiments only and is not intended to limit the invention. As used herein, the singular terms “a,” “an” and “the” are intended to include the plural forms as well, unless the context clearly indicates otherwise. As used herein, the term “and/or” includes any and all combinations of one or more of the associated listed items. It will be understood that when an element is referred to as being “connected” or “coupled” to another element, it may be directly connected or coupled to the other element or intervening elements may be present.

Similarly, it will be understood that when an element such as a layer, region or substrate is referred to as being “on” another element, it can be directly on the other element or intervening elements may be present. In contrast, the term “directly” means that there are no intervening elements. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

Additionally, the embodiment in the detailed description will be described with sectional views as ideal exemplary views of the inventive concept. Accordingly, shapes of the exemplary views may be modified according to manufacturing techniques and/or allowable errors. Therefore, the embodiments of the inventive concept are not limited to the specific shape illustrated in the exemplary views, but may include other shapes that may be created according to manufacturing processes. Areas exemplified in the drawings have general properties, and are used to illustrate specific shapes of elements. Thus, this should not be construed as limited to the scope of the inventive concept.

It will be also understood that although the terms first, second, third etc. may be used herein to describe various elements, these elements should not be limited by these terms. These terms are only used to distinguish one element from another element. Thus, a first element in some embodiments could be termed a second element in other embodiments without departing from the teachings of the present invention. Exemplary embodiments of aspects of the present inventive concept explained and illustrated herein include their complementary counterparts. The same reference numerals or the same reference designators denote the same elements throughout the specification.

FIG. 2 is a cross-sectional view illustrating a light emitting diode according to embodiments of the inventive concept.

Referring to FIG. 2, light emitting diode 100 according to embodiments of the inventive concept may include a multi-quantum-well light emitting layer 110 between first and second electrode layers 109 and 113, and a buffer layer 108 having concave-convex patterns 106. The concave-convex patterns 106 of the buffer layer 108 may prevent total reflection of light generated from the multi-quantum-well light emitting layer 110 to improve the light extraction efficiency of the light emitting diode 100.

Thus, the light emitting diode 100 according to embodiments of the inventive concept may increase or maximize light emitting efficiency.

The light emitting diode 100 may be connected to a receptor substrate 117 by stud bumps 119. The receptor substrate 117 may be a silicon substrate. The stud bumps 119 may electrically connect the first electrode layer 109 and a reflection layer 116 to the receptor substrate 117. An ohmic metal layer 115 may be disposed between the first electrode layer 109 and the stud bump 119. A base electrode layer 118 may be disposed between the stud bump 119 and the receptor substrate 117.

The first and second electrode layers 109 and 113 may include n-type gallium nitride (n-GaN) and p-type gallium nitride (p-GaN), respectively. The multi-quantum-well light emitting layer 110 may include indium-gallium nitride (InGaN) well layers 111 and gallium nitride (GaN) barrier layers 112 which are alternately stacked. The indium-gallium nitride well layer 111 may have an energy band gap smaller than that of the gallium nitride barrier layers 112 and generate light of a green wavelength band (e.g., about 510 nm to about 560 nm)

The buffer layer 108 may include a semi-polar gallium nitride (GaN) plane. The semi-polar gallium nitride may have a refractive index of about 1.22 or more. The buffer layer 108 may include the concave-convex patterns 106 having a semi-polar gallium nitride ( 1̅101) plane 107 and a gallium nitride (0001) incline face 142. The gallium nitride (0001) incline face 142 may be inclined with respect to the semi-polar gallium nitride ( 1̅101) plane 107 by an angle of about 62 degrees. In other words, light perpendicularly incident to the semi-polar gallium nitride ( 1̅101) plane 107 may be condensed within an angle of about 28 degrees or less. Additionally, the concave-convex patterns 106 may not total-reflect the light perpendicularly incident to the semi-polar gallium nitride ( 1̅101) plane 107, but the concave-convex patterns 106 may output the light perpendicularly incident to the semi-polar gallium nitride ( 1̅101) plane 107 outward. Distances between convex parts of the concave-convex patterns 106 may be equal to or less than a half width of each of the convex parts of the concave-convex patterns 106. For example, the concave-convex patterns 106 having widths of 4 μm may be spaced apart from each other by about 2 μm or less. The concave-convex patterns 106 may increase the light extraction efficiency. The concave-convex patterns 106 may be used as a seed layer of the buffer layer 108. The semi-polar gallium nitride plane having a large area of the buffer layer 108 may be formed by the concave-convex patterns 106.

Thus, the light emitting diode 100 according to embodiments of the inventive concept may increase or maximize light emitting efficiency.

A method of manufacturing the above light emitting diode 100 will be described in detail with reference to the drawings.

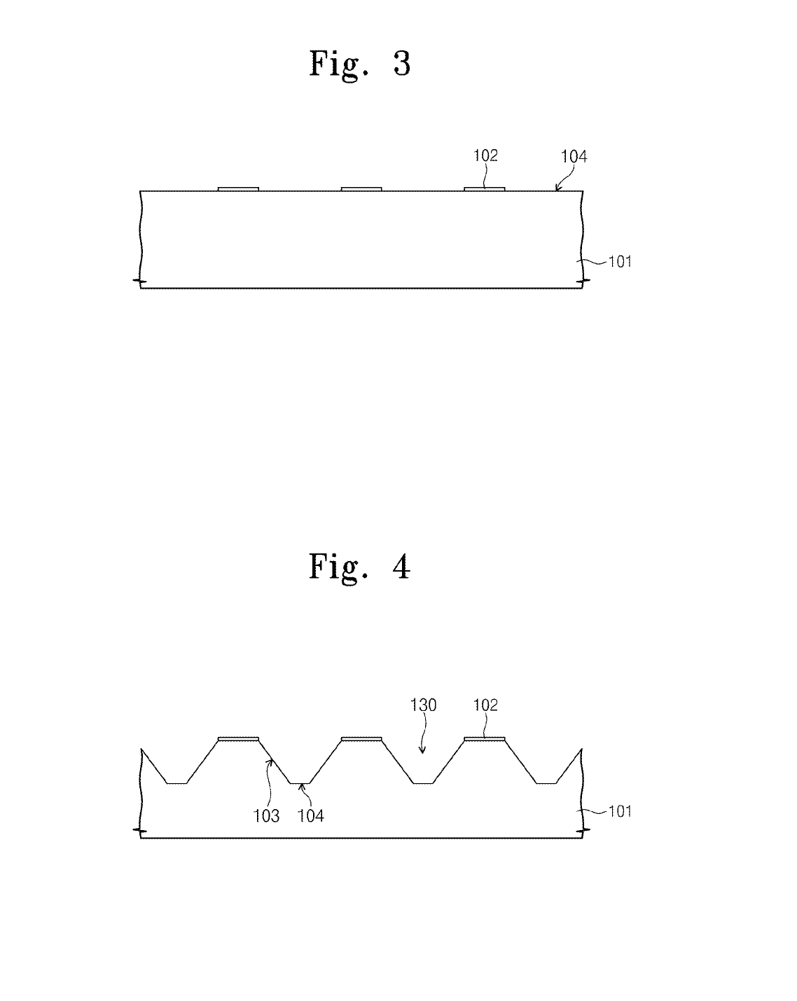

FIGS. 3 to 12 cross-sectional views illustrating a method of manufacturing a light emitting diode according to embodiments of the inventive concept.

Referring to FIG. 3, dielectric mask patterns 102 are formed on a silicon (100) substrate 101. The dielectric mask patterns 102 may be formed by a patterning process using a photoresist patterns (not shown). The dielectric mask patterns 102 may include silicon nitride (SiNₓ). The dielectric mask patterns 102 may be formed in stripe-shape. The silicon (100) substrate 101 may have a top surface corresponding to a silicon (100) plane 104. The dielectric mask patterns 102 may cover portions of the top surface of the silicon (100) substrate 101.

Referring to FIG. 4, the silicon (100) substrate 101 exposed from the dielectric mask patterns 102 may be etched to form trenches 130 having incline sidewalls of a silicon (111) facet 103. The silicon (100) substrate 101 may be etched by potassium hydroxide (KOH). For example, the potassium hydroxide (KOH) may have different etch rates according to crystal faces of silicon when the silicon (100) substrate 101 is etched. The (111) crystal face of the silicon may function as an etch stop face during etching of the silicon (100) substrate 101 by the potassium hydroxide (KOH). Thus, it is possible to form the trenches 130 having the incline sidewalls of the silicon (111) facet 103. Additionally, a bottom surface of the trench 130 may correspond to the silicon (100) plane 104.

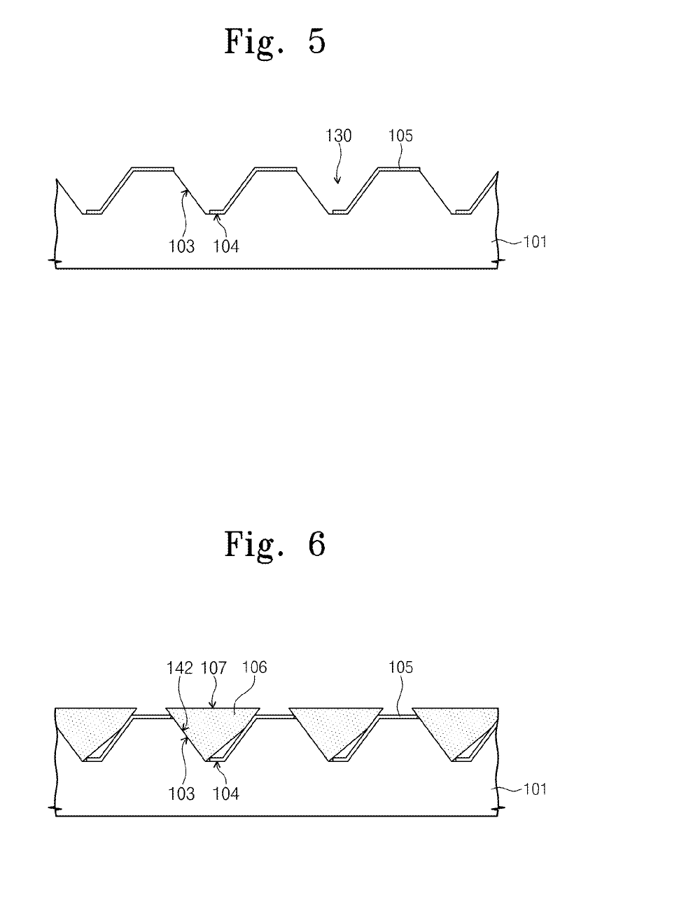

Referring to FIG. 5, the dielectric mask patterns 102 are removed, and then second dielectric mask patterns 105 may be formed to selectively expose the silicon (111) facet 103. The dielectric mask patterns 105 may include silicon oxide (SiO₂) or silicon nitride (SiN) formed by a chemical vapor deposition (CVD) process. The second dielectric mask patterns 105 may be formed by a patterning process using a second photoresist patterns (not shown).

Referring to FIG. 6, semi-polar gallium nitride (GaN) triangle layers 106 (e.g., concave parts) having semi-polar faces may be grown the silicon (111) facets 103. The semi-polar gallium nitride triangle layers 106 having the semi-polar faces may be formed in the trenches 130 in triangle shape by metal organic chemical vapor deposition (MOCVD) process. The semi-polar gallium nitride triangle layers 106 having the semi-polar faces may be grown on the silicon (111) facets 103 in a <0001> direction. Each of the semi-polar gallium nitride triangle layers 106 having the semi-polar faces may include a gallium nitride (0001) incline face 142 on the silicon (111) facet 103 and a semi-polar gallium nitride ( 1̅101) plane 107.

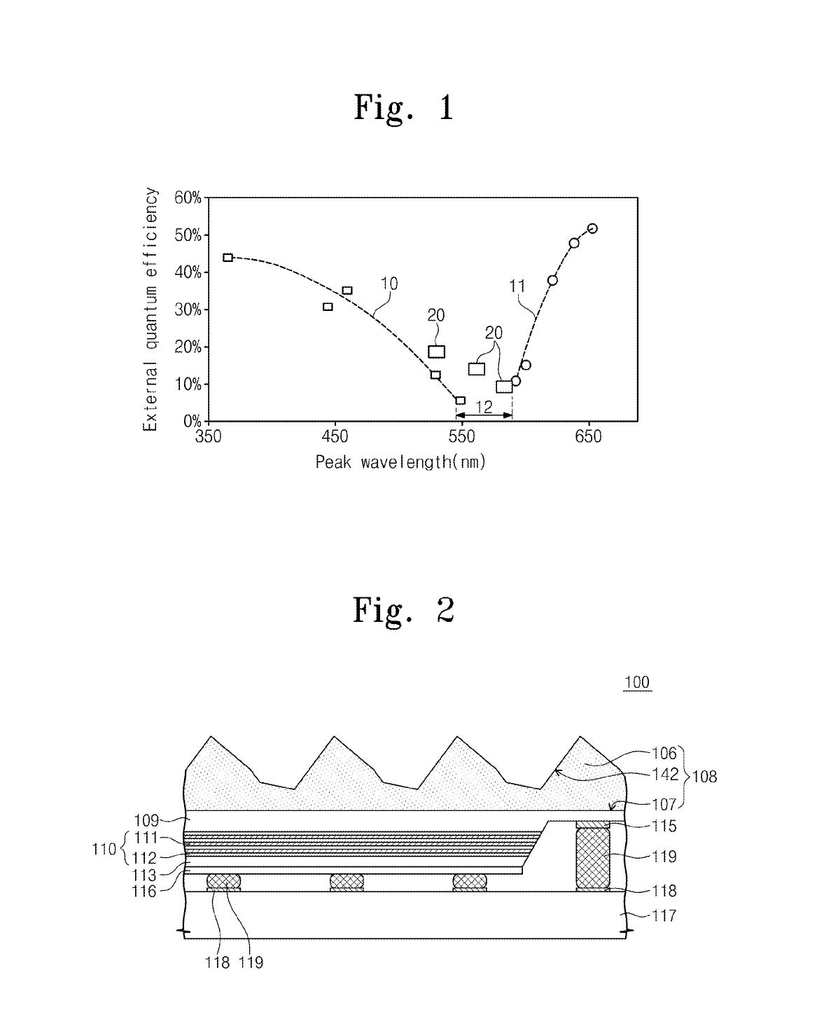

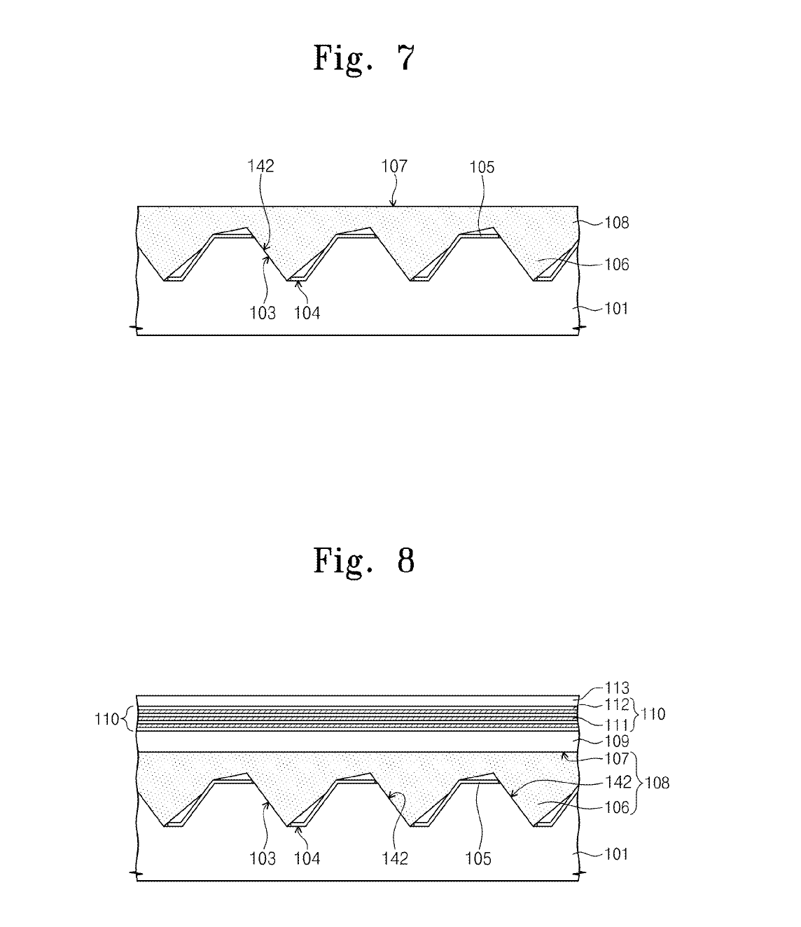

Referring to FIGS. 1 and 7, the semi-polar gallium nitride triangle layers 106 having the semi-polar faces may be laterally grown to form a buffer layer 108 having a large area. The buffer layer 108 may be formed by a MOCVD process of epitaxial lateral overgrowth (ELOG) condition. The ELOG condition may include a method changing a growth condition in the MOCVD process. The buffer layer 108 may have a semi-polar gallium nitride ( 1̅101) plane 107 of the large area. Additionally, the buffer layer 108 may include concave-convex patterns 106 corresponding to the semi-polar gallium nitride patterns.

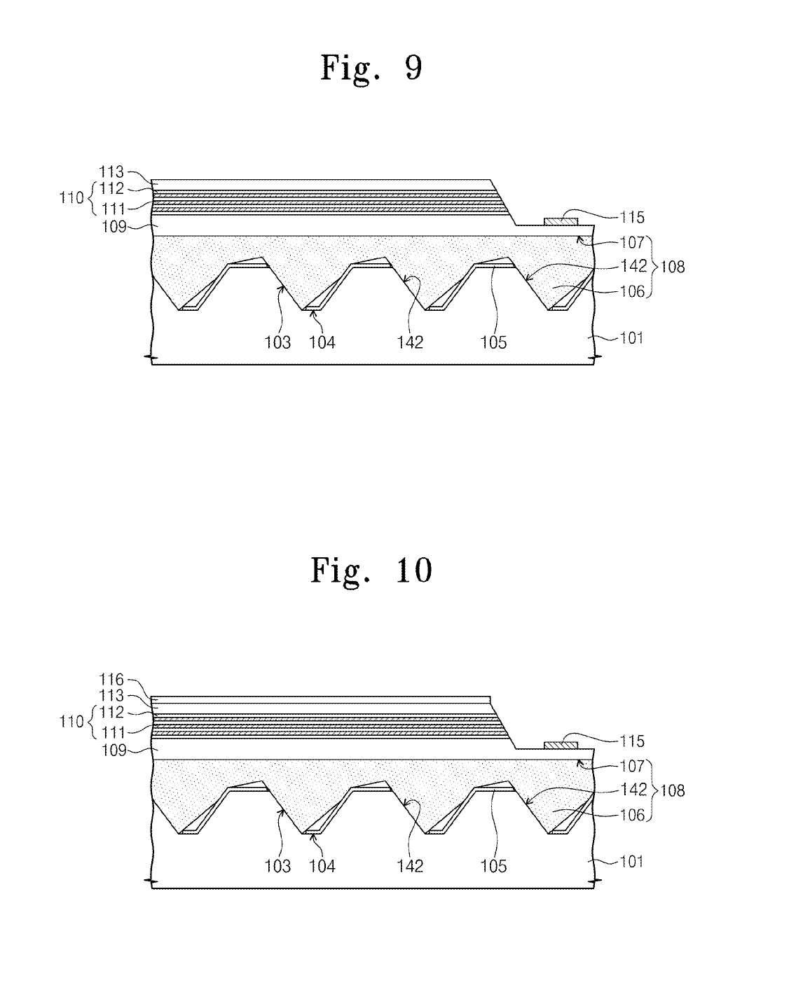

Referring to FIG. 8, a first electrode layer 109 and a multi-quantum-well light emitting layer 110, and a second electrode layer 113 may be sequentially formed on the buffer layer 108. The first electrode layer 109 may include n-type gallium nitride (n-GaN) formed by a MOCVD process. For example, the first electrode layer 109 may include gallium nitride doped with dopants (e.g., silicon) of a first conductivity by a concentration within a range of about 3×10¹⁸/cm³ to about 7×10¹⁸/cm³.

The multi-quantum-well light emitting layer 110 may include indium-gallium nitride well layers 111 and gallium nitride barrier layers 112 which are formed by MOCVD processes. The indium-gallium nitride well layer 111 may include indium having a high concentration within a range of about 25% to about 40%. The indium-gallium nitride well layer 111 may have a thickness of about 5 nm or less, and the gallium nitride barrier layer 112 may have a thickness of about 10 nm. The multi-quantum-well light emitting layer 110 may include three to seven pairs of the indium-gallium nitride well layer 111 and the gallium nitride barrier layer 112.

The second electrode layer 113 may include p-type gallium nitride (p-GaN) formed by a MOCVD process. For example, the second electrode layer 113 may include gallium nitride doped with dopants (e.g., magnesium) of a second conductivity by a concentration within a range of about 5×10¹⁷/cm³ to about 1×10¹⁸/cm³. Even though not shown in the drawings, a stress control layer may be disposed between the first electrode layer 109 and the multi-quantum-well light emitting layer 110. Additionally, a current blocking layer or an electron blocking layer (EBL) may be disposed between the multi-quantum-well light emitting layer 110 and the second electrode layer 113.

Referring to FIG. 9, portions of the second electrode layer 113 and the multi-quantum-well light emitting layer 110 are removed to expose the first electrode layer 109 and then an ohmic metal layer 115 is formed on the exposed first electrode layer 109. The first electrode layer 109 may be exposed by contact holes (not shown). The contact holes may be formed by a patterning process using third photoresist patterns (not shown) and an etch process (e.g., a dry-etching process or a wet-etching process). The dry-etching process may be performed by an inductive coupled plasma (ICP) method. The contact holes may have a depth within a range of about 0.8 μm to 1.2 μm. The ohmic metal layer 115 may be formed on the first electrode layer 109 in the contact hole by a metal deposition process and an etching process removing the metal on the second electrode layer 113 using a fourth photoresist pattern (not shown) as an etch mask.

Referring to FIG. 10, a reflection layer 116 is formed on the second electrode layer 113. The reflection layer 116 may include a metal such as gold, silver, aluminum, and/or tungsten. The reflection layer 116 may be formed by a lift-off process using a fifth photoresist patterns (not shown). For example, the fifth photoresist patterns may be formed on the ohmic metal layer 115 and the first electrode layer 109 and then a metal layer may be formed on the fifth photoresist patterns and the second electrode layer 113. Thereafter, the fifth photoresist patterns and the metal layer on the fifth photoresist patterns may be removed to form the reflection layer 116 on the second electrode layer 113. Here, the metal layer may be deposited by a thermal evaporation method, an e-beam evaporation method, or a sputtering method. Even though not shown in the drawings, a diffusion preventing layer may be formed between the second electrode layer 113 and the reflection layer 116.

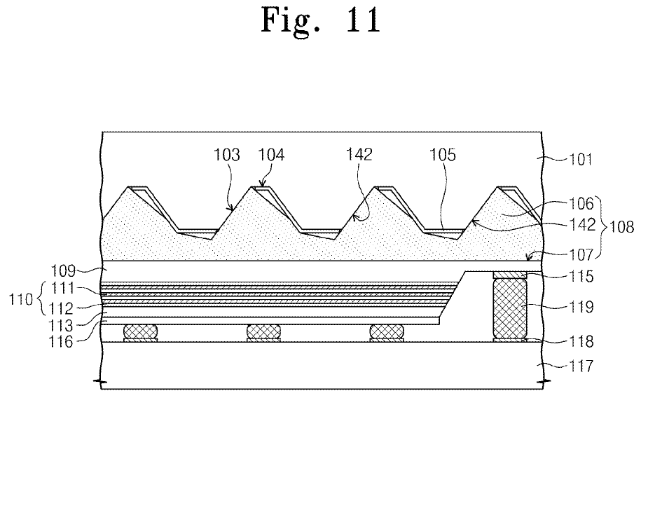

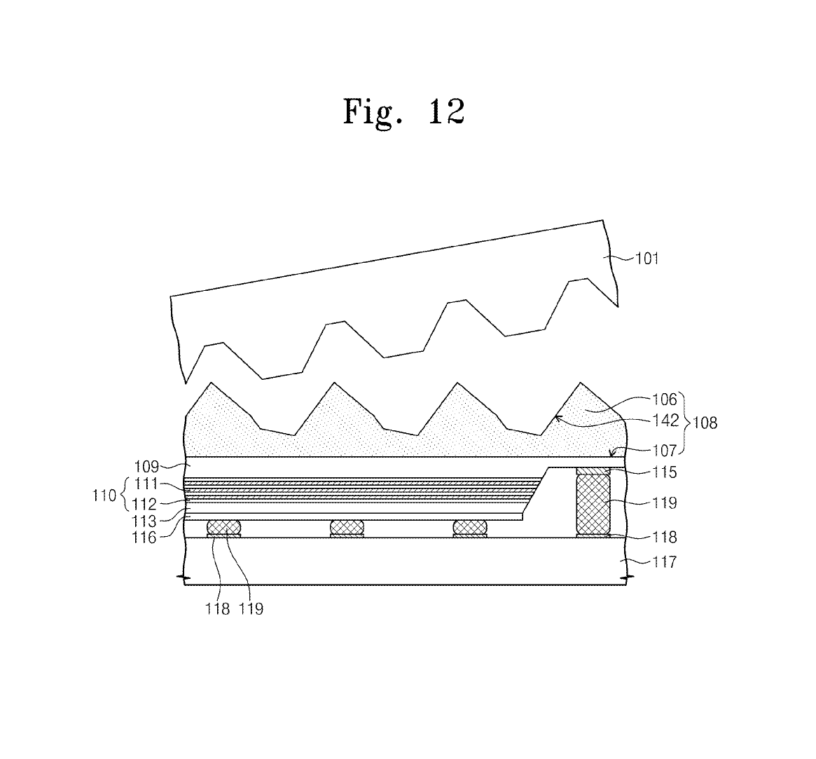

Referring to FIG. 11, stud bumps 119, base electrode layers 118, and a receptor substrate 117 are connected to the reflection layer 116 and the ohmic metal layer 115. The receptor substrate 117 may be bonded to the reflection layer 116 and the ohmic metal layer 115 through the stud bumps 119 and the base electrode layer 118 in a flip-chip bonding method. The receptor substrate 117 may include a silicon substrate having high thermal conductivity and high mechanical hardness. The stud bumps 119 may include gold having high ductility.

Referring to FIG. 12, the silicon (100) substrate 101 is removed. The silicon (100) substrate opaque with respect to visible light may be removed. The silicon (100) substrate 101 may be removed by a chemical lift-off method using a potassium hydroxide (KOH) solution. If the receptor substrate 117 is formed of silicon, the receptor substrate 117 may be protected by a photoresist or a passivation layer from the potassium hydroxide (KOH) solution. The concave-convex patterns 106 of the buffer layer 108 may be exposed by the removal of the silicon (100) substrate 101. The concave-convex patterns 106 may increase the light extraction efficiency without an additional texturing process with respect to the buffer layer 108.

Thus, the light emitting diode 100 according to embodiments of the inventive concept may increase or maximize light emitting efficiency.

As described above, according to embodiments of the inventive concept, the trenches having the silicon (111) incline facets are formed in the silicon (100) substrate and then the semi-polar GaN patterns having the GaN (0001) incline faces and the semi-polar GaN ( 1̅101) planes are grown the silicon (111) incline facets. The semi-polar GaN patterns may be laterally grown to form the buffer layer having the large area of the semi-polar GaN ( 1̅101) plane covering an entire top surface of the silicon substrate. The first electrode layer, the light emitting layer, and the second electrode layer are formed the buffer layer. Thereafter, the silicon (100) substrate is removed from the buffer layer. The GaN concave-convex patterns of the buffer layer may increase extraction efficiency of the light generated from the InGaN light emitting layer.

Thus, it is possible to increase or maximize the light emitting efficiency and productivity due to the light emitting diodes and the methods of manufacturing the same according to embodiments of the inventive concept.

While the inventive concept has been described with reference to example embodiments, it will be apparent to those skilled in the art that various changes and modifications may be made without departing from the spirit and scope of the inventive concept. Therefore, it should be understood that the above embodiments are not limiting, but illustrative. Thus, the scope of the inventive concept is to be determined by the broadest permissible interpretation of the following claims and their equivalents, and shall not be restricted or limited by the foregoing description.

What is claimed is:

1. A light emitting diode comprising:
a first electrode layer;
a light emitting layer on the first electrode layer;
a second electrode layer on the light emitting layer; and
a buffer layer formed on the second electrode layer, the buffer layer having concave-convex patterns increasing extraction efficiency of light generated from the light emitting layer.

2. The light emitting diode of claim 1, wherein convex parts of the concave-convex patterns are spaced apart from each other by a distance equal to or less than a half width of each of the convex parts.

3. The light emitting diode of claim 2, wherein each of the convex parts of the concave-convex patterns has at least one gallium nitride (0001) incline face.

4. The light emitting diode of claim 1, wherein the buffer layer has a semi-polar gallium nitride ( 1̅101) plane.

5. The light emitting diode of claim 1, wherein the light emitting layer includes indium-gallium nitride well layers and gallium nitride barrier layers.

6. The light emitting diode of claim 1, wherein the buffer layer has a refractive index of about 1.22 or more.

7. A method of manufacturing a light emitting diode, comprising:
partially etching a silicon (100) substrate to form trenches exposing silicon (111) incline facets;
forming a buffer layer having gallium nitride (0001) incline faces grown from the silicon (111) incline facets and a semi-polar gallium nitride ( 1̅101) plane grown higher than a top surface of the silicon (100) substrate;
forming a first electrode layer on the semi-polar gallium nitride ( 1̅101) plane;
forming a light emitting layer on the first electrode layer;
forming a second electrode layer on the light emitting layer; and
removing the silicon (100) substrate.

8. The method of claim 7, wherein forming the buffer layer comprises:
forming mask patterns exposing the silicon (111) incline facets of the trenches;
forming semi-polar gallium nitride patterns having gallium nitride (0001) incline faces grown from the silicon (111) inclined facets and the semi- polar gallium nitride ( 1̅101) planes; and
laterally growing the semi-polar gallium nitride patterns to connect the semi-polar gallium nitride ( 1̅101)planes to each other.

9. The method of claim 8, wherein the semi-polar gallium nitride patterns are laterally grown by a metal organic chemical vapor deposition method of a lateral growth condition.

10. The method of claim 7, wherein the silicon (100) substrate is removed by a chemical lift-off method using a potassium hydroxide (KOH) solution.

11. The method of claim 7, wherein forming the trenches comprises:
forming mask patterns on the silicon (100) substrate;
removing portions of the silicon (100) substrate by an etching process using the mask patterns as etch masks, thereby forming the trenches exposing the silicon (111) incline facets; and
removing the mask patterns.

12. The method of claim 11, wherein the etching process is a wet etching process using a potassium hydroxide (KOH) solution.

13. The method of claim 11, wherein the mask patterns include silicon nitride.

14. The method of claim 7, further comprising:
bonding the first electrode layer and the second electrode layer to a receptor substrate through stud bumps and an ohmic metal layer in a flip-chip bonding method.
